(19) United States
(12) Patent Application Publication
(10) Pub. No.: US 2012/0239957 A1
(43) Pub. Date: Sep. 20, 2012

(54) MULTIMEDIA PLAYER HAVING BATTERY BACKUP POWER

(75) Inventors: HUNG-CHANG HSIAO, NEW TAIPEI CITY (TW); CHEN-FAN WANG, NEW TAIPEI CITY (TW)

(73) Assignee: SANGEAN ELECTRONICS INC., NEW TAIPEI CITY (TW)

(21) Appl. No.: 13/171,541

(22) Filed: Jun. 29, 2011

(30) Foreign Application Priority Data
Mar. 16, 2011 (TW) 100108900

(51) Int. Cl. G06F 1/30; H05K 7/00

(52) U.S. Cl. 713/340; 361/679.31

(57) ABSTRACT

A multimedia player having battery backup power has a housing, a battery seat, a rechargeable battery and a circuit module. The battery seat is formed on a periphery of the housing and has a battery connector electrically connected with a power circuit of a power module mounted inside the housing. The rechargeable battery is conveniently and directly mounted on the battery seat and supplies backup power to the power circuit of the power module through the battery connector. As the power circuit is connected with an AC power source, the power circuit further converts the AC power into DC power to charge the rechargeable battery when the AC power supply is normal, thereby reducing the frequency of battery replacement.

### BACKGROUND OF THE INVENTION

1. Field of the Invention

The present invention relates to a multimedia player, and more particularly to a multimedia player having battery backup power additionally providing operating power to the multimedia player with a rechargeable battery.

2. Description of the Related Art

The development and popularization of multimedia technology brings into play the multimedia formats, such as MP3, WMA and the like, which are far more efficient than the earlier audio CD format in terms of memory storage. Hence, the portable multimedia players, such as MP3, MP4 and the like, have rapidly grown and replaced the obsolete CD player and become the mainstream products of the music players in the market due to their compact size, portability and better protection against data corruption.

Although being compact and portable, the foregoing portable multimedia players are mainly dedicated for users to listen through earphones instead of through high-volume and high-power speakers. However, wearing earphones to listen may not be the best option to users intending to use the portable multimedia players at home. To tackle the disadvantage, a conventional multimedia player is available to connect with multimedia storage devices, such as MP3 and MP4 players, and play the retrieved multimedia information through a speaker.

With reference to FIG. 4, the conventional multimedia player has a housing 90, a portable multimedia player socket 91, a power connector 92, a display 93, a speaker 94 and an operation module 95. The portable multimedia player socket 91 is electrically connected with an external portable multimedia player to receive multimedia information stored in the external multimedia player. The power connector 92 is connected to the AC mains. The operation module 95 serves to generate multiple operation signals.

A circuit module is mounted inside the housing 90, is electrically connected with the multimedia player socket 91, the power connector 92, the display 93, the speaker 94 and the operation module 95, is activated by the operation signals transmitted from the operation module 95, receives multimedia information from the multimedia player socket 91, displays the multimedia information on the display 93, outputs analog audio signals to the speaker 94 to broadcast, and is connected to the AC mains through the power connector 92 to supply operating power required by the multimedia player.

The foregoing multimedia player having a portable multimedia player operated thereon is usually a stationary device instead of a portable device; furthermore, the audio signals need to be amplified. Thus, the power required by the multimedia player must be higher than that required by a portable multimedia player. The multimedia player is normally supplied by AC power, which is rectified to DC power as the operating power to the multimedia player. Hence, the operation of the multimedia player is limited by the availability of the AC mains. When the multimedia player is used outdoors, such as on an outing or a camping occasion, an extension cord or a small power generator must be prepared additionally, rendering the operation of the multimedia player very inconvenient.

### SUMMARY OF THE INVENTION

An objective of the present invention is to provide a multimedia player having battery backup power additionally providing operating power with a rechargeable battery.

To achieve the foregoing objective, the multimedia player having battery backup power has a housing, a battery seat, a rechargeable battery and a circuit module.

The housing has at least one memory device slot, a power connector, a display, a speaker and an operation module. The at least one memory device slot is mounted on a periphery of the housing, and is adapted to respectively connect with at least one external memory device and respectively read multimedia information stored in the memory device. The power connector is mounted on the periphery of the housing and adapted to electrically connect to the AC mains. The display is mounted on the periphery of the housing. The speaker is mounted on the periphery of the housing. The operation module is mounted on the periphery of the housing and is operated to output operation signals.

The battery seat is formed on the periphery of the housing and has a battery connector mounted therein.

The rechargeable battery is selectively mounted in the battery seat and electrically connected with the battery connector.

The circuit module is mounted inside the housing and has a power circuit and a multimedia processing circuit. The power circuit is electrically connected with the power connector and the battery connector and electrically connected with the rechargeable battery through the battery connector. The multimedia processing circuit is electrically connected with the at least one memory device slot, the power connector, the display, the speaker and the operation module.

As the battery seat is formed on the housing, the rechargeable battery can be conveniently and directly mounted on the battery seat and electrically connected with a power circuit of a circuit module so that the power circuit can acquire backup power in addition to the mains power. When the AC mains is normal, the mains power can go through the power connector to supply operating power required by the entire multimedia player. When the AC mains fails, the rechargeable battery can still supply the operating power required by the multimedia player through the battery connector. Given the two power sources, the multimedia player can be operated indoors with the power supplied by the AC mains and operated outdoors with the power supplied by the rechargeable battery.

Other objectives, advantages and novel features of the invention will become more apparent from the following detailed description when taken in conjunction with the accompanying drawings.

### BRIEF DESCRIPTION OF THE DRAWINGS

FIG. 1 is a partially exploded perspective view of a multimedia player having battery backup power in accordance with the present invention;

FIG. 2 is another partially exploded perspective view of a multimedia player having battery backup power in FIG. 1;

FIG. 3 is a functional block diagram of a circuit module of the multimedia player having battery backup power in FIG. 1; and

FIG. 4 is a perspective view of a conventional multimedia player.

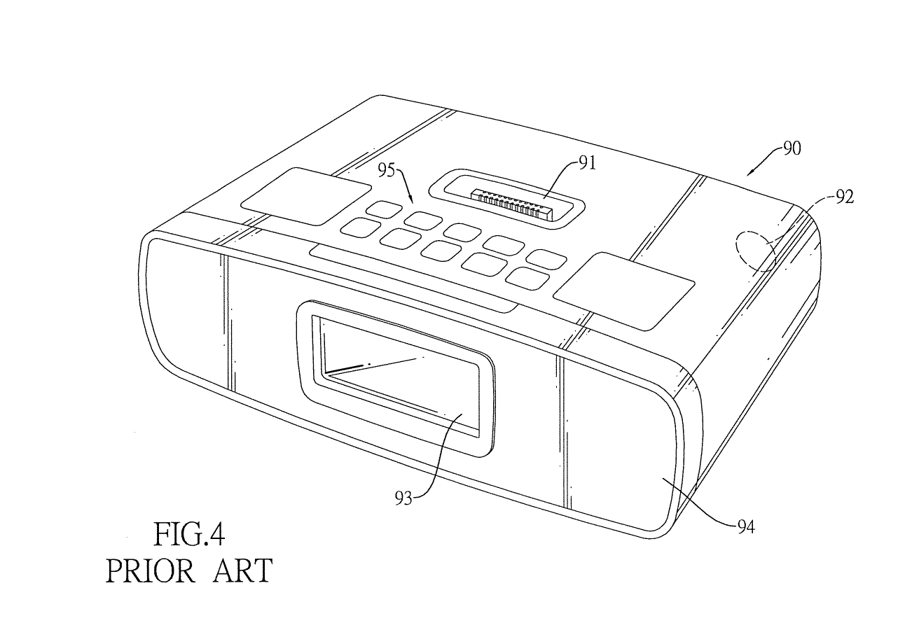

### DETAILED DESCRIPTION OF THE INVENTION

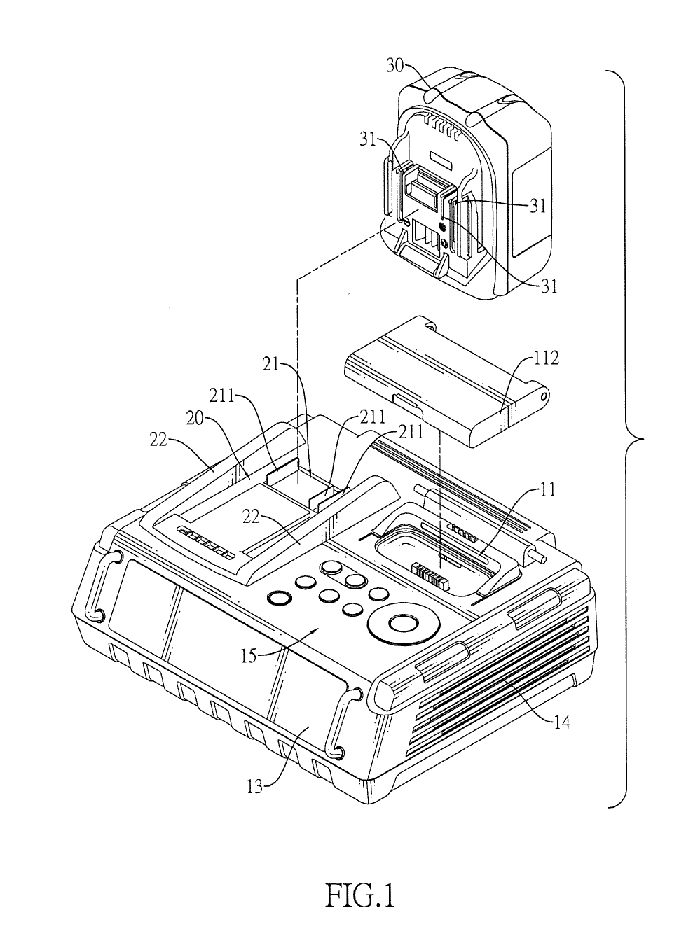

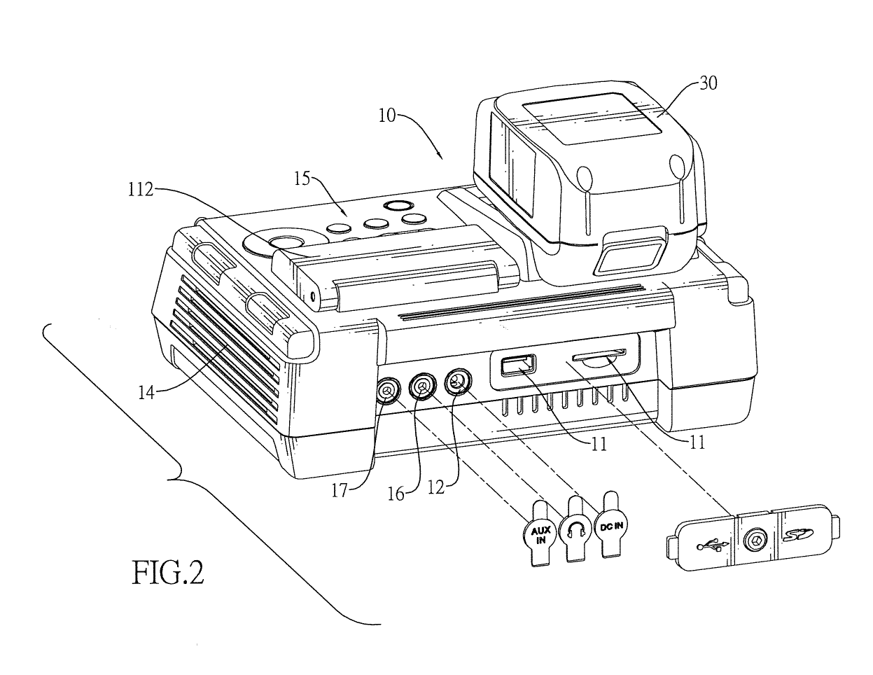

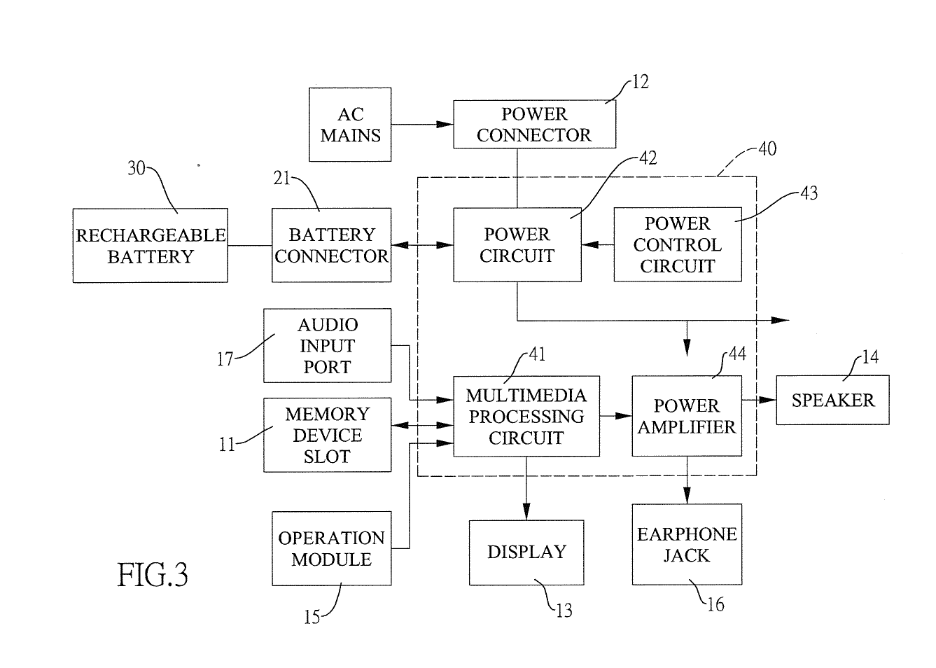

With reference to FIGS. 1 to 3, a multimedia player having battery backup power has a housing 10, a battery seat 20, a rechargeable battery 30 and a circuit module 40.

The housing 10 has at least one memory device slot 11, a power connector 12, a display 13, a speaker 14, an operation module 15, an earphone jack 16 and an audio input port 17 mounted on a periphery of the housing. The at least one memory device slot 11 serves to respectively connect with at least one external memory device and respectively read multimedia information stored in the memory device. The power connector 12 is electrically connected to the AC mains. The operation module 15 serves to be operated by users and output corresponding operation signals. The earphone jack 16 serves to be connected with an external earphone. The audio input port 17 serves to receive external analog audio signals. In the present embodiment, the housing 10 has multiple memory device slots 11 and a lid 112. The memory device slots 11 include an SD card slot, a USB slot and a portable multimedia player slot. The lid 112 is pivotally mounted on the periphery of the housing to cover the portable multimedia player slot. The operation module 15 pertains to a button set or a wireless remote control receiver capable of receiving external wireless remote control signals.

The battery seat 20 is formed on the periphery of the housing 10 and has a battery connector 21 mounted therein. In the present embodiment, the battery seat 20 has two parallel walls 22 respectively formed on and protruding upwardly from two opposite sides of the battery seat 20. The battery connector 21 is mounted on one end of the battery seat 20 and between the parallel walls 22 and has three electrodes 211.

The rechargeable battery 30 is selectively mounted in the battery seat 20 and is electrically connected with the battery connector 21. In the present embodiment, the rechargeable battery 30 has three power slots 31 respectively aligning with the three electrodes 211 so that the three electrodes 211 are inserted into and electrically connected with the corresponding power slots when the rechargeable battery 30 is slidably mounted in the battery seat 20 from between the two parallel walls 22 of the battery seat 20.

The circuit module 40 is mounted inside the housing 10 and has a multimedia processing circuit 41, a power circuit 42, a power control circuit 43 and a power amplifier 44. The multimedia processing circuit 41 is electrically connected with the memory device slots 11, the display 13 and the operation module 15 and the audio input port 17, is electrically connected with the speaker 14 and the earphone jack 16 through the power amplifier 44, is activated after receiving an operation signal from the operation module 15, receives multimedia information from the memory device slots 11, outputs the multimedia information to the display 13 for the display 13 to display the multimedia information, and outputs analog audio signals to the power amplifier 44 for amplification and to the speaker 14 to broadcast the audio signals. After the multimedia processing circuit 41 receives the analog audio signals from the audio input port 17, the audio signals are amplified by the power amplifier 44 and outputted to the speaker 14 for broadcasting through the speaker 14 or outputted to the earphone jack 16 for receiving through a connected external earphone. The power circuit 42 is electrically connected with the AC mains through the power connector 12 so as to convert the mains power from AC power to DC power to supply the power required by the entire multimedia player and is electrically connected with the rechargeable battery 30 through the battery connector 21. The power control circuit 43 is electrically connected with the power circuit 42 to control the power circuit 43 to simultaneously supply the power required by the multimedia player and charge the rechargeable battery 30 through the battery connector 21 with the mains power when the AC mains is normal and to supply the power required by the multimedia player with the rechargeable battery 30 when the AC mains fails.

When the AC mains is normal, the power control circuit 43 controls the power circuit 42 to simultaneously supply power with the mains power and fully charge the rechargeable battery 30. When the multimedia player is brought to and operated on an outdoor occasion, the power control circuit 43 can still switch to the rechargeable battery 30 to supply the power required by the entire multimedia player to normally operate even if the mains power is unavailable. The multimedia player is convenient to be used on an outdoor occasion as there is no need to prepare an extension cord or a small power generator.

Additionally, the rechargeable battery 30 can be slidably mounted in the battery seat 20 from between the two walls 22 of the battery seat 20 and then abut against and connect with the battery connector 21. Similarly, the rechargeable battery 30 can be slidably dismounted from the battery seat 20 by disconnecting from the battery connector 21 and being removed from between the two walls 22 of the battery seat 20. Hence, users can mount or dismount the rechargeable battery 30 without requiring any additional tool.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A multimedia player having battery backup power comprising:
a housing having:
at least one memory device slot mounted on a periphery of the housing, and adapted to respectively connect with at least one external memory device and respectively read multimedia information stored in the memory device;
a power connector mounted on the periphery of the housing and adapted to electrically connect to the AC mains;
a display mounted on the periphery of the housing;
a speaker mounted on the periphery of the housing; and
an operation module mounted on the periphery of the housing and operated to output operation signals;
a battery seat formed on the periphery of the housing and having a battery connector mounted therein;
a rechargeable battery selectively mounted in the battery seat and electrically connected with the battery connector; and
a circuit module mounted inside the housing and having:
a power circuit electrically connected with the power connector and the battery connector and electrically connected with the rechargeable battery through the battery connector; and
a multimedia processing circuit electrically connected with the at least one memory device slot, the power connector, the display, the speaker and the operation module.

2. The multimedia player as claimed in claim 1, wherein
the battery seat has two parallel walls respectively formed on and protruding upwardly from two opposite sides of the battery seat;
the battery connector is mounted on one end of the battery seat and between the parallel walls and has three electrodes; and
the rechargeable battery has three power slots respectively aligning with the three electrodes so that the three electrodes are inserted into and electrically connected with the corresponding power slots when the rechargeable battery is slidably mounted in the battery seat.

3. The multimedia player as claimed in claim 1, wherein the housing has:
multiple memory device slots including an SD card slot, a USB slot and a portable multimedia player slot; and
a lid pivotally mounted on the periphery of the housing to cover the portable multimedia player slot.

4. The multimedia player as claimed in claim 2, wherein the housing has:
multiple memory device slots including an SD card slot, a USB slot and a portable multimedia player slot; and
a lid pivotally mounted on the periphery of the housing to cover the portable multimedia player slot.

5. The multimedia player as claimed in claim 1, wherein the circuit module has:
a multimedia processing circuit electrically connected with the memory device slots, the display and the operation module, receiving multimedia information from the memory device slots, outputting the multimedia information to the display for the display to display the multimedia information, and outputting analog audio signals to the speaker to broadcast the audio signals through the speaker;
a power circuit adapted to electrically connect with a mains power through the power connector so as to convert the mains power from AC power to DC power and supply power required by the entire multimedia player and electrically connected with the rechargeable battery through the battery connector;
a power control circuit electrically connected with the power circuit, controlling the power circuit to simultaneously supply power required by the multimedia player and charge the rechargeable battery through the battery connector with the mains power when the AC mains is normal and to supply power required by the multimedia player with the rechargeable battery when the AC mains fails; and
a power amplifier electrically connected with the speaker and the multimedia processing circuit to receive and amplify analog audio signals and output the analog audio signals to the speaker for broadcasting through the speaker.

6. The multimedia player as claimed in claim 2, wherein the circuit module has:
a multimedia processing circuit electrically connected with the memory device slots, the display and the operation module, receiving multimedia information from the memory device slots, outputting the multimedia information to the display for the display to display the multimedia information, and outputting analog audio signals to the speaker to broadcast the audio signals through the speaker;
a power circuit adapted to electrically connect with a mains power through the power connector so as to convert the mains power from AC power to DC power and supply power required by the entire multimedia player and electrically connected with the rechargeable battery through the battery connector;
a power control circuit electrically connected with the power circuit, controlling the power circuit to simultaneously supply power required by the multimedia player and charge the rechargeable battery through the battery connector with the mains power when the AC mains is normal and to supply power required by the multimedia player with the rechargeable battery when the AC mains fails; and
a power amplifier electrically connected with the speaker and the multimedia processing circuit to receive and amplify analog audio signals and output the analog audio signals to the speaker for broadcasting through the speaker.

7. The multimedia player as claimed in claim 3, wherein the circuit module has:
a multimedia processing circuit electrically connected with the memory device slots, the display and the operation module, receiving multimedia information from the memory device slots, outputting the multimedia information to the display for the display to display the multimedia information, and outputting analog audio signals to the speaker to broadcast the audio signals through the speaker;
a power circuit adapted to electrically connect with a mains power through the power connector so as to convert the mains power from AC power to DC power and supply power required by the entire multimedia player and electrically connected with the rechargeable battery through the battery connector;
a power control circuit electrically connected with the power circuit, controlling the power circuit to simultaneously supply power required by the multimedia player and charge the rechargeable battery through the battery connector with the mains power when the AC mains is normal and to supply power required by the multimedia player with the rechargeable battery when the AC mains fails; and
a power amplifier electrically connected with the speaker and the multimedia processing circuit to receive and amplify analog audio signals and output the analog audio signals to the speaker for broadcasting through the speaker.

8. The multimedia player as claimed in claim 4, wherein the circuit module has:
a multimedia processing circuit electrically connected with the memory device slots, the display and the operation module, receiving multimedia information from the memory device slots, outputting the multimedia information to the display for the display to display the multimedia information, and outputting analog audio signals to the speaker to broadcast the audio signals through the speaker;
a power circuit adapted to electrically connect with a mains power through the power connector so as to convert the mains power from AC power to DC power and supply power required by the entire multimedia player and electrically connected with the rechargeable battery through the battery connector;
a power control circuit electrically connected with the power circuit, controlling the power circuit to simultaneously supply power required by the multimedia player and charge the rechargeable battery through the battery connector with the mains power when the AC mains is normal and to supply power required by the multimedia player with the rechargeable battery when the AC mains fails; and
a power amplifier electrically connected with the speaker and the multimedia processing circuit to receive and amplify analog audio signals and output the analog audio signals to the speaker for broadcasting through the speaker.

9. The multimedia player as claimed in claim 1, wherein the operation module is a button set.

10. The multimedia player as claimed in claim 2, wherein the operation module is a button set.

11. The multimedia player as claimed in claim 7, wherein the operation module is a button set.

12. The multimedia player as claimed in claim 8, wherein the operation module is a button set.

13. The multimedia player as claimed in claim 1, wherein the operation module is a wireless remote control receiver outputting a corresponding operation signal after receiving an external wireless remote control signal.

14. The multimedia player as claimed in claim 2, wherein the operation module is a wireless remote control receiver outputting a corresponding operation signal after receiving an external wireless remote control signal.

15. The multimedia player as claimed in claim 7, wherein the operation module is a wireless remote control receiver outputting a corresponding operation signal after receiving an external wireless remote control signal.

16. The multimedia player as claimed in claim 8, wherein the operation module is a wireless remote control receiver outputting a corresponding operation signal after receiving an external wireless remote control signal.

17. The multimedia player as claimed in claim 7, wherein
the housing further has an audio input port for receiving external analog audio signals and electrically connected with the multimedia processing circuit; and
after the multimedia processing circuit receives the analog audio signals from the audio input port, the analog audio signals are amplified by the power amplifier and outputted to the speaker for broadcasting through the speaker.

18. The multimedia player as claimed in claim 8, wherein
the housing further has an audio input port for receiving external analog audio signals and electrically connected with the multimedia processing circuit; and
after the multimedia processing circuit receives the analog audio signals from the audio input port, the analog audio signals are amplified by the power amplifier and outputted to the speaker for broadcasting through the speaker.
